(19) United States
(12) Patent Application Publication
(10) Pub. No.: US 2024/0112842 A1
(43) Pub. Date: Apr. 4, 2024

(54) INDUCTOR AND METHOD OF FORMING THE SAME

(71) Applicant: Taiwan Semiconductor Manufacturing Company, Ltd., Hsinchu (TW)

(72) Inventors: Po-Sheng Lu, Hsinchu City (TW); Chien-Hung Liu, Hsinchu County (TW); Nuo Xu, San Jose, CA (US)

(73) Assignee: Taiwan Semiconductor Manufacturing Company, Ltd., Hsinchu (TW)

(21) Appl. No.: 18/152,726

(22) Filed: Jan. 10, 2023

Related U.S. Application Data
(60) Provisional application No. 63/412,544, filed on Oct. 3, 2022.

(51) Int. Cl. H01F 17/02

(52) U.S. Cl. CPC H01F 17/02; H01L 28/10; H01F 2017/0086

(57) ABSTRACT

An inductor and a method of forming the same are provided. The inductor includes a patterned wire structure. The patterned wire structure includes a conductive core, a dielectric film and a magnetic shell. The conductive core includes a pair of end surfaces and an outer surface between the pair of end surfaces. The dielectric film covers the outer surface. The magnetic shell covers the dielectric film. The dielectric film is between the conductive core and the magnetic shell.

### CROSS-REFERENCE TO RELATED APPLICATION

This application claims the priority benefit of U.S. provisional application Ser. No. 63/412,544, filed on Oct. 3, 2022. The entirety of the above-mentioned patent application is hereby incorporated by reference herein and made a part of this specification.

### BACKGROUND

An inductor is a passive component which can be integrated in a semiconductor package such as 2D package, 2.5D package or 3D package. The integrated inductor may be used as a voltage regulator, a radio frequency transceiver and etc. The inductor having a larger inductance and a higher quality factor (Q factor) is expected. However, when the inductor operates under high-frequency alternating current (AC), it would be accompanied with a high eddy current, which results in a degraded of the inductance and the Q factor of the inductor.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a 3D schematic view of an inductor according to some embodiments of the present disclosure.

FIGS. 2A to 2C are schematic cross-sectional views of an inductor according to some embodiments of the present disclosure.

FIG. 3 is a schematic cross-sectional view of a mechanism work out in an inductor according to some embodiments of the present disclosure.

FIG. 4 is a schematic cross-sectional view of an inductor according to some embodiments of the present disclosure.

FIG. 5 is a schematic cross-sectional view of an inductor according to some embodiments of the present disclosure.

FIG. 6 is a schematic cross-sectional view of an inductor according to some embodiments of the present disclosure.

FIG. 7A is a 3D schematic view of a semiconductor die according to some embodiments of the present disclosure.

FIGS. 7B to 7E are schematic plan views of an inductor according to some embodiments of the present disclosure.

FIG. 8 is a 3D schematic view of a semiconductor die according to some embodiments of the present disclosure.

FIGS. 9A to 9I are schematic cross-sectional views illustrating structures formed at various stages of a method of forming an inductor according to some embodiments of the present disclosure.

FIGS. 10A to 10E are schematic cross-sectional views illustrating structures formed at various stages of a method of forming an inductor according to some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, “around”, “about”, “approximately”, or “substantially” shall generally mean within 20 percent, or within 10 percent, or within 5 percent of a given value or range. Numerical quantities given herein are approximate, meaning that the term “around”, “about”, “approximately”, or “substantially” can be inferred if not expressly stated.

According to embodiments of the present disclosure, an inductor is described. In some embodiments, the inductor includes a conductive core, a dielectric film covering an outer surface of the conductive core and a magnetic shell covering the dielectric film, so that an inductance and a Q factor of the inductor can be improved while operating under both low-frequency and high-frequency condition.

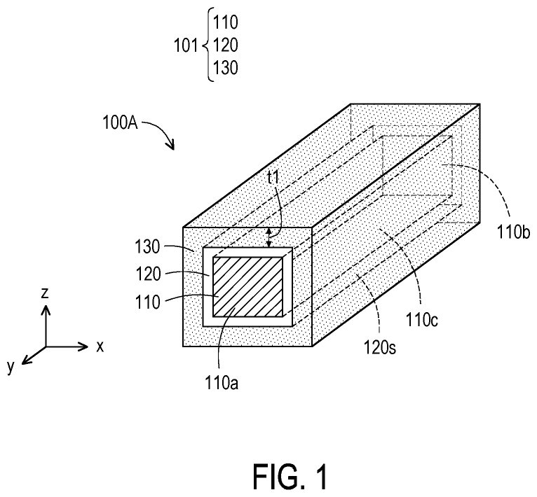

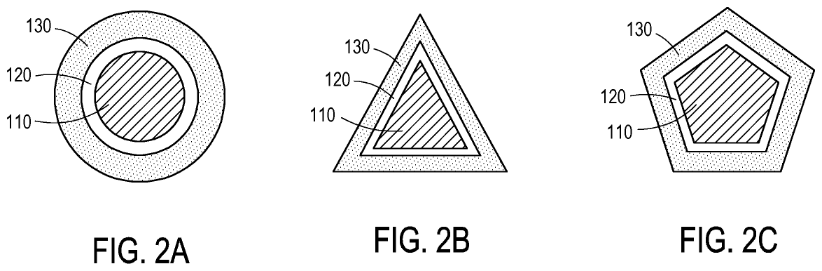

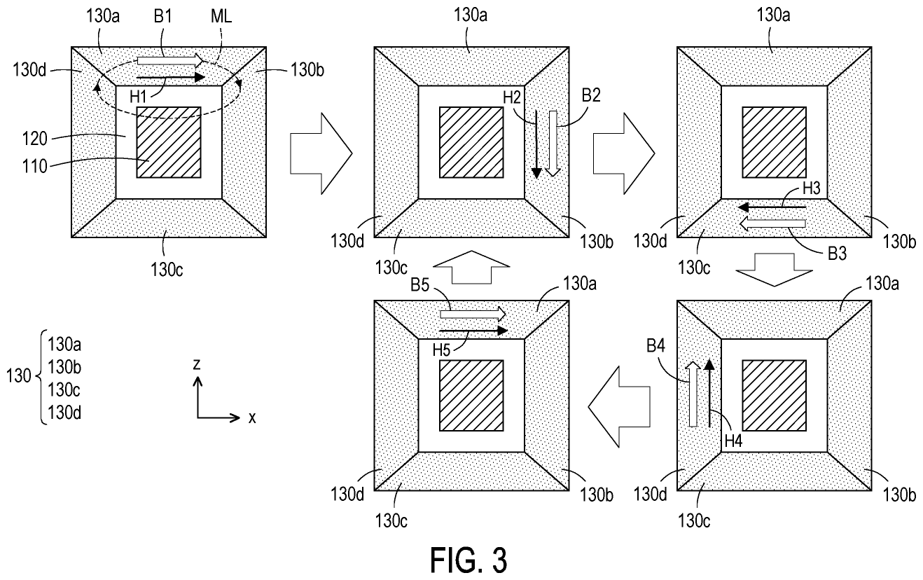

FIG. 1 is a 3D schematic view of an inductor 100A according to some embodiments of the present disclosure. FIGS. 2A to 2C are schematic cross-sectional views of the inductor 100A according to some alternative embodiments of the present disclosure. FIG. 3 is a schematic cross-sectional view of a mechanism work out in the inductor 100A according to some embodiments of the present disclosure.

Referring to FIG. 1, an inductor 100A is described, and the inductor 100A includes a patterned wire structure 101. The patterned wire structure 101 includes a conductive core 110, a dielectric film 120 and a magnetic shell 130. The conductive core 110 includes a pair of end surfaces 110a, 110b and an outer surface 110c between the pair of end surfaces 110a and 110b. In some embodiments, the material of the conductive core 110 includes metal, such as copper, silver, aluminum, gold, titanium, tantalum, tungsten, a combination thereof, an alloy of the above-mentioned metals or other suitable conductive materials. The dielectric film 120 may be a dielectric shell. The dielectric film 120 covers the outer surface 110c of the conductive core 110. In some embodiments, the material of the dielectric film 120 includes silicon oxide, silicon nitride, aluminum oxide, silicon carbide, amorphous silicon, polysilicon, a combination thereof or other suitable dielectric materials. The magnetic shell 130 covers the dielectric film 120 and the dielectric film 120 is between the conductive core 110 and the magnetic shell 130. That is, the magnetic shell 130 covers the outer surface 120s of the dielectric film 120 and the conductive core 110. In other words, the conductive core 110 is electrically isolated from the magnetic shell 130 by the dielectric film 120. In some embodiments, the dielectric film 120 is in contact with the outer surface 110c of the conductive core 110. In some embodiments, the material of the magnetic shell 130 includes nickel-iron alloy, cobalt, iron, cobalt-iron alloy, silicon steel, a combination thereof or other suitable materials. In some embodiments, the magnetic shell 130 includes a single magnetic film or multiple stacked magnetic films with the same or different materials.

In some embodiments, the end surfaces 110a and 110b of the conductive core 110 are exposed, but it is not limited thereto. In other embodiments, the dielectric film 120 also covers the end surfaces 110a and 110b of the conductive core 110. In an embodiment where the dielectric film 120 covers the pair of end surfaces 110a and 110b of the conductive core 110, the magnetic shell 130 may or may not cover the pair of end surfaces of the dielectric film 120.

In FIG. 1, the patterned wire structure 101 extends along y direction and the cross section of the patterned wire structure 110 is in x-z plane. Here, the x direction, the y direction and the z direction are perpendicular to each other. This shows that a normal line of the cross section of the patterned wire 101 is substantially parallel to the extending direction of the patterned wire structure 110 (that is, y direction). In this embodiment, the shape of the cross-section of the conductive core 110 is a rectangular shape, but it is not limited thereto. The shape of the cross-section of the conductive core 110 may be a circular shape, an oval shape, a polygonal shape or other suitable shapes. For example, as shown in FIG. 2A, the shape of the cross-section of the conductive core 110 is a circular shape or an oval shape. In FIG. 2B, the shape of the cross-section of the conductive core 110 is a triangular shape. In FIG. 2C, the shape of the cross-section of the conductive core 110 is a pentagon. The shape of the cross-section of the conductive core 110 may be adjusted according to the actual requirements.

Since the inductor 100A includes the conductive core 110, the dielectric film 120 covering the conductive core 110 and the magnetic shell 130 covering the dielectric film 120, a positive feedback mechanism may work out in the inductor 100A, so that the inductor 100A can have high inductance and high Q factor. The positive feedback mechanism is described in FIG. 3.

In FIG. 3, for interpretation purpose, the magnetic shell 130 is divided into four portions, that is, an upper portion 130a, a right portion 130b, a bottom portion 130c and a left portion 130d. The upper portion 130a is disposed on the upper side of the dielectric film, the right portion 130b is disposed on the right side of the dielectric film, the bottom portion 130c is disposed on the bottom side of the dielectric film, and the left portion 130d is disposed on the left side of the dielectric film. The upper portion 130a is connected to the right portion 130b, the right portion 130b is connected to the bottom portion 130c, the bottom portion 130c is connected to the left portion 130d and the left portion 130d is connected to the upper portion 130a. It is appreciated that the border between the adjacent two portions of the magnetic shell 130 may not exist and it is only shown for better understanding of the mechanism of the inductor 100A described below. Besides, the cross section of the conductive core 110 is a rectangular shape in this embodiment, but it is not limited thereto, as long as the magnetic shell 130 covers the dielectric film 120 and the dielectric film 120 covers the outer surface 110c of the conductive core 110, the following mechanism may happen in the inductor 100A.

Referring to FIG. 3, when the inductor 100A is triggered by a current passing through the conductive core 110, an external magnetic field H1, in a positive x direction, may be applied to the upper portion 130a, and due to the magnetic property of the upper portion 130a, an induced magnetic field B1 is induced by the external magnetic field H1. Due to the magnetic hysteresis, the intensity of the induced magnetic field B1 may be stronger than the intensity of the external magnetic field H1 applied to the upper portion 130a. FIG. 3 schematically shows one of the magnetic field line ML of the induced magnetic field B1. The magnetic field line ML of the induced magnetic field B1 is a closed loop in clockwise direction. As the magnetic field line ML of the induced magnetic field B1 shown, a part of the induced magnetic field B1 may direct to the right portion in the negative z direction, so that an external magnetic field H2 can be applied to the right portion 130b. In some embodiments, other external magnetic fields may also be applied to the magnetic portion nearby, such as the bottom portion 130c and the left portion 130d, due to the induced magnetic field B1. Since the mechanism is identical to each portion of the magnetic shell 130, only the external magnetic field H2 applied to the right portion 130b is discussed below. The intensity of the external magnetic field H2 is proportional to the intensity of the induced magnetic field B1, which means the stronger the induced magnetic field B1 is induced, the stronger the external magnetic field H2 is applied to the right portion 130b. Then, similarly, an induced magnetic field B2 is induced by the external magnetic field H2 and the intensity of the induced magnetic field B2 may be stronger than the intensity of the external magnetic field H2 applied to the right portion 130b. Besides, a part of the induced magnetic field B2 may direct to a negative x direction, so that an external magnetic field H3 can be applied to the bottom portion 130c. The intensity of the external magnetic field H3 is proportional to the intensity of the induced magnetic field B2. Then, similarly, an induced magnetic field B3 is induced by the external magnetic field H3 and the intensity of the induced magnetic field B3 may be stronger than the intensity of the external magnetic field H3 applied to the bottom portion 130c. A part of the induced magnetic field B3 may direct to a positive z direction, so that an external magnetic field H4 can be applied to the left portion 130d. The intensity of the external magnetic field H4 is proportional to the intensity of the induced magnetic field B3. Then, similarly, an induced magnetic field B4 is induced by the external magnetic field H4 and the intensity of the induced magnetic field B4 may be stronger than the intensity of the magnetic field H4 applied to the left portion 130d. A part of the induced magnetic field B4 may direct to the upper portion 130a in the positive x direction, so that an external magnetic field H5 can be applied to the upper portion 130a. The intensity of the external magnetic field H5 is proportional to the intensity of the induced magnetic field B4. Then an induced magnetic field B4 is induced by the external magnetic field H5.

As describe above, the intensity of the induced magnetic field (or the magnetic flux of the induced magnetic field) may continuously increase due to the positive feedback of the adjacent magnetic portions until reaching the magnetic saturation of the magnetic shell 130 which depends on the B-H curve of the magnetic material in the magnetic shell 130. Since the inductor 100A includes the magnetic shell 130 surrounds the conductive core 110, the afore-mentioned positive feedback mechanism can perform well, so that the inductor 100A can have high inductance and high Q factor.

In some embodiments, a thickness t1 (shown in FIG. 1) of the magnetic shell 130 is between about 0.06 μm and about 0.5 μm. Within this range, the eddy current generated due to the operation under the alternating current environment may have little impact to the magnetic field of the inductor 100A, so that the inductor 100A can have significantly improved inductance and Q factor under high-frequency condition. That is to say, the inductor 100A performs well under both low-frequency and high-frequency condition. When the thickness t1 of the magnetic shell 130 is larger than about 0.5 μm, the eddy current generated due to the operation under the alternating current environment may have stronger impact to the magnetic field of the inductor 100A, so that the intensity of the magnetic field of the inductor 100A may be suppressed and result in the decreasing of the inductance and the Q factor under high frequency condition.

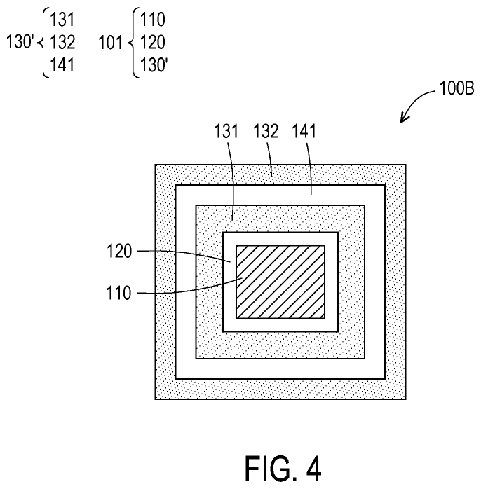

FIG. 4 is a schematic cross-sectional view of an inductor 100B according to some embodiments of the present disclosure. It should be noted herein that, in embodiment provided in FIG. 4, element numerals and partial content of the embodiments provided in FIG. 1 are followed, the same or similar reference numerals being used to represent the same or similar elements, and description of the same technical content being omitted. For a description of an omitted part, reference may be made to the foregoing embodiment, and the descriptions thereof are omitted herein.

Referring to FIG. 4, the difference between the present embodiment to the embodiment of FIG. 1 is that the magnetic shell 130′ of the inductor 100B includes magnetic films, such as a first magnetic film 131 and a second magnetic film 132, and at least one insulating film, such as a first insulating film 141. The first magnetic film 131 covers the outer surface of the dielectric film 120. The second magnetic film 132 covers the first magnetic film 131. The first insulating film 141 is disposed between the first magnetic film 131 and the second magnetic film 132. That is to say, the magnetic films 131, 132 are spaced apart from one other by the at least one insulating film 141. In other words, the magnetic films 132, 132 are not in contact with each other. FIG. 4 schematically shows two magnetic films and one insulating film between them, but it is not limited. The number of magnetic films and the insulating films are not limited and can be adjusted according to the actual requirement, as long as the adjacent two magnetic films are separated by an insulating film. The first magnetic film 131 and the second magnetic film 132 may include the same material as the magnetic shell 130 described in FIG. 1. The material of the first magnetic film 131 may be the same with or different from the material of the second magnetic film 132. The insulating film 141 may include the same material as the dielectric film 120. The material of the insulating film 141 may be the same with or different from the material of the dielectric film 120.

Since the inductor 100B has multiple magnetic films 131, 132 spaced apart from one other by the insulating film 141 and surrounding the dielectric film 120 covering the conductive core 110, the inductor 100B can work out with the positive feedback mechanism similar as described in FIG. 3, so that the inductor 100B having high inductance and high Q factor can be achieved.

In some embodiments, each separated magnetic film 132, 132 has a thickness ranging from about 0.06 μm to about 0.5 μm. Within this range, since the magnetic shell 130′ has multiple magnetic films 131, 132 spaced apart from one other by the insulating film 141, the thickness of the magnetic shell 130 can be increased without raising the eddy current impact, that is, the eddy current generated due to the operation under the alternating current environment may have little impact to the magnetic field of the inductor 100B. Therefore, the inductor 100B can have significantly improved inductance and Q factor under both low-frequency and high-frequency condition.

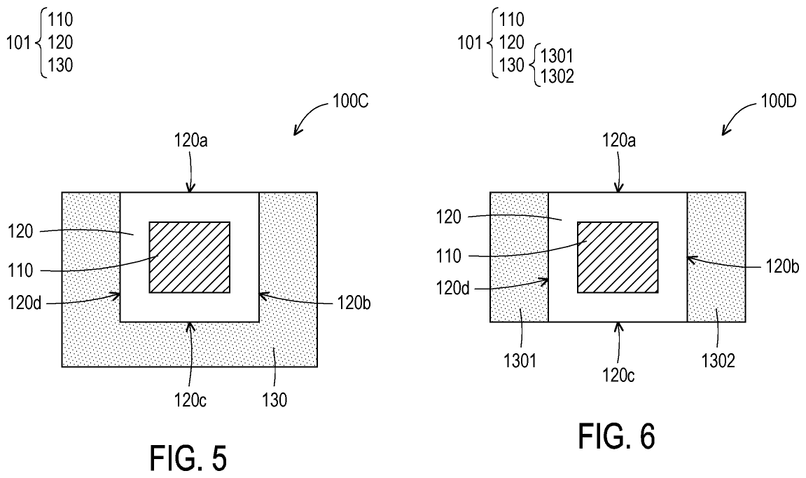

FIG. 5 is a schematic cross-sectional view of an inductor 100C according to some embodiments of the present disclosure. It should be noted herein that, in embodiment provided in FIG. 5, element numerals and partial content of the embodiments provided in FIG. 1 are followed, the same or similar reference numerals being used to represent the same or similar elements, and description of the same technical content being omitted. For a description of an omitted part, reference may be made to the foregoing embodiment, and the descriptions thereof are omitted herein.

Referring to FIG. 5, the difference between the present embodiment to the embodiment of FIG. 1 is that one side of the dielectric film 120 is exposed. For example, the dielectric film 120 has four sides 120a, 120b, 120c and 120d covering the outer surface of the conductive core 110, respectively and correspondingly. The magnetic shell 130 is disposed on three sides among the four sides of the dielectric film 120, (such as sides 120b, 120c and 120d), and the remaining one side of the dielectric film 120 (such as sides 120a) is exposed. When the inductor 100C is triggered, even though one side of the dielectric film 120 is not covered by the magnetic shell, the magnetic shell 130 on other sides 120b, 120c and 120d of the dielectric film 120 can still work out the positive feedback mechanism similar as described in FIG. 3. Therefore, the inductor 100C can have improved inductance and Q factor. It is noted that FIG. 5 takes the inductor 100C with a conductive core 110 having a rectangular cross-sectional shape as an example, but is not intended to limit the present invention. The conductive core 110 may have different cross-sectional shape as described in FIG. 2A to 2C.

FIG. 6 is a schematic cross-sectional view of an inductor 100D according to some embodiments of the present disclosure. It should be noted herein that, in embodiment provided in FIG. 6, element numerals and partial content of the embodiments provided in FIGS. 1 and 5 are followed, the same or similar reference numerals being used to represent the same or similar elements, and description of the same technical content being omitted. For a description of an omitted part, reference may be made to the foregoing embodiment, and the descriptions thereof are omitted herein.

Referring to FIG. 6, the difference between the present embodiment to the embodiment of FIG. 1 is that the magnetic shell 130 of the inductor 100D is disposed on two sides of the dielectric film 120. For example, the magnetic shell 130 includes a first portion 1301 and a second portion 1302. The first portion 1301 and the second portion 1302 are disposed on two opposite sides of the dielectric film 120 (such as sides 120b, 120d) respectively. That is to say, the first portion 1301 and the second portion 1302 are disconnected. In other embodiments, the first portion 1301 and the second portion 1302 may be connected and disposed on the two adjacent sides of the dielectric film 120, for example on sides 120b and 120c, which is not limited. Since the inductor 100C includes the magnetic shell 130 covers at least two sides of the dielectric film 120 covering the outer surface of the conductive core 110, the inductor 100C can have improved inductance and Q factor due to the positive feedback mechanism similar as described in FIG. 3. It is noted that FIG. 6 takes the inductor 100D with a conductive core 110 having a rectangular cross-sectional shape as an example, but is not intended to limit the present invention. The conductive core 110 may have different cross-sectional shape as described in FIG. 2A to 2C.

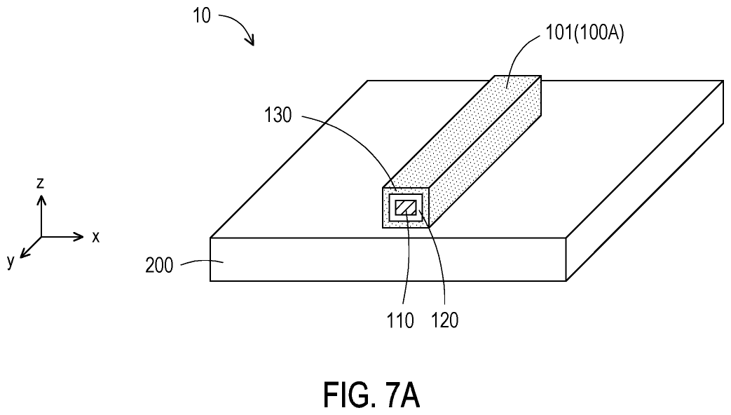

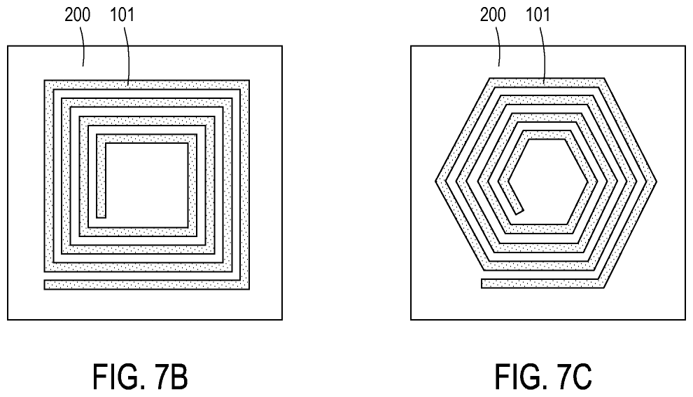

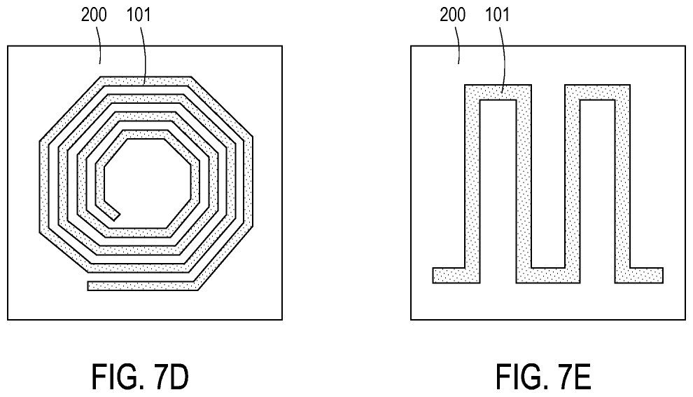

FIG. 7A is a 3D schematic view of an inductor 100A integrated in a semiconductor die 10 according to some embodiments of the present disclosure. FIGS. 7B to 7E are schematic plan views of the inductor 100A according to some embodiments of the present disclosure. It should be noted herein that, in embodiments provided in FIGS. 7A to 7E, element numerals and partial content of the embodiments provided in FIG. 1 are followed, the same or similar reference numerals being used to represent the same or similar elements, and description of the same technical content being omitted. For a description of an omitted part, reference may be made to the foregoing embodiment, and the descriptions thereof are omitted herein. For clear illustration, an interconnect structure of the semiconductor die 10 is omitted in FIGS. 7A to 7E.

Referring to FIG. 7A, the inductor 100A may be integrated in the semiconductor die 10. That is, the patterned wire structure 101 may be embedded in the semiconductor die 10. The inductor 100A may be other type of the inductors described above, for example, the inductor 100B in FIG. 4, the inductor 100c in FIG. 5, the inductor 100d in FIG. 6 or the combination thereof, which is not limited. Besides, the conductive core 110 may have different cross-sectional shape as described in FIG. 2A to 2C. The semiconductor die 10 includes a semiconductor substrate 200 and an interconnect structure (not shown) disposed on the semiconductor substrate 200. The semiconductor substrate 200 may be formed of silicon, which is not limited. The semiconductor substrate 200 may also be formed of other group III, group IV, and/or group V elements, such as germanium, gallium, arsenic, and combinations thereof. The semiconductor substrate 200 may also be in the form of silicon-on-insulator (SOI). In some embodiments, the semiconductor substrate 200 may include one or more active and/or passive device (not shown), for example, transistors, capacitors, resistors, diodes, photodiodes and/or the like. The interconnect structure may include stacked dielectric layers (such an inter-layer dielectric (ILD)/inter-metal dielectric layers (IMDs)) and interconnect wirings (such as conductive lines and vias) between the stacked dielectric layers. The material of the stacked dielectric layers may be a low-K dielectric material, such as phosphosilicate glass (PSG), borophosphosilicate glass (BPSG), FSG, SiOxCy, Spin-On-Glass (SOG), Spin-On-Polymers, silicon carbon material, compounds thereof, composites thereof, combinations thereof, or the like. In some embodiments, the interconnect wirings include copper wirings, silver wirings, gold wirings, tungsten wirings, tantalum wirings, aluminum wirings, a combination thereof, or the like. In some embodiments, the interconnect wirings provide electrical connections between the one or more active and/or passive devices of the semiconductor substrate 200. In some embodiments, the patterned wire structure 101 is embedded in the interconnect structure of the semiconductor die 10 and electrically connects with the interconnect wirings of the interconnect structure.

In FIG. 7A, the inductor 100A is an in-plane inductor, which lies above the semiconductor substrate 10 and an extending direction of a portion of the patterned wire structure 101 is substantially perpendicular to a normal line of the semiconductor substrate 200. In this embodiment, the normal line of the semiconductor substrate 200 is in z direction. That is to say, the patterned wire structure 101 may extend in x-y plane. In FIG. 7A, the patterned wire structure 101 extends along a line path in y direction, which is a one-dimension extension, so that the patterned wire structure 101 may be in a shape of a line or a strip, but it is not limited. In other embodiments, the patterned wire structure 101 can extend along a spiral path, a serpentine path or other suitable paths, which is a two-dimension extension in the x-y plane. The spiral path may be a circular spiral path, a square spiral path, a hexagonal spiral path, an octagonal spiral path or other suitable spiral paths. The serpentine path may be a continuous S-shaped path, a square wave-like path, a zigzag path or the like. For example, in FIG. 7B, the patterned wire structure 101 extends along a square spiral path. In FIG. 7C, the patterned wire structure 101 extends along a hexagonal spiral path. In FIG. 7D, the patterned wire structure 101 extends along an octagonal spiral path. In FIG. 7E, the patterned wire structure 101 extends along a square wave-like path. The path which the patterned wire structure 101 extends along can be adjusted according to the actual requirement of the product. For example, the inductor used as a voltage regulator has a patterned wire structure extending along a simple line path. The inductor used as a radio frequency transceiver may have a patterned wire structure extending along a complicated spiral path due to the large inductance requirement.

In some embodiments, the inductor 100A includes multiple patterned wire structures 101 stacked along z direction and electrical connected to each other. For example, the inductor 100A includes multiple patterned wire structures 101 extending along a spiral path in x-y plane and stacked on each other in the z direction to form a 3-dimensional spiral path with the center axis substantially parallel to the normal line of the semiconductor substrate 200.

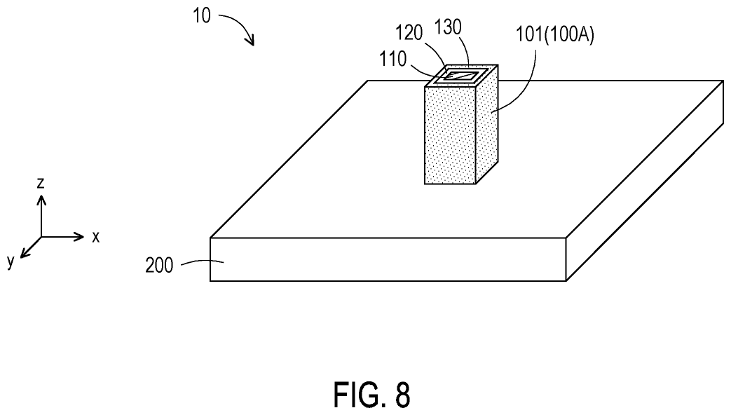

FIG. 8 is a 3D schematic view of an inductor 100A integrated in a semiconductor die 10 according to some embodiments of the present disclosure. It should be noted herein that, in embodiments provided in FIG. 8, element numerals and partial content of the embodiments provided in FIGS. 1 and 7A are followed, the same or similar reference numerals being used to represent the same or similar elements, and description of the same technical content being omitted. For a description of an omitted part, reference may be made to the foregoing embodiment, and the descriptions thereof are omitted herein. For clear illustration, an interconnect structure of the semiconductor die 10 is omitted in FIG. 8.

Referring to FIG. 8, the difference between the present embodiment to the embodiment in FIG. 7A is that the inductor 100A is an out-of-plane inductor, which stands above the semiconductor substrate 10 and an extending direction of a portion of the patterned wire structure 101 is substantially parallel to the normal line of the semiconductor substrate 200. For example, the patterned wire structure 101 extends along the z direction which is parallel to the normal line of the semiconductor substrate 200 directing to the z direction. Although FIG. 8 shows that the patterned wire structure 101 extends along a line path, it is not intended to limit the present embodiment. The patterned wire structure in the present embodiment may also extends along a spiral shape, a serpentine shape or other suitable paths in a plane parallel to the z direction, similar as described above in FIGS. 7B to 7E. In some embodiments, the inductor 100A includes multiple patterned wire structures 101 stacked along x direction or y direction and electrical connected to each other. For example, the inductor 100A includes multiple patterned wire structures 101 extending along a spiral path in x-z plane and stacked on each other in the y direction to form a 3-dimensional spiral path with the center axis substantially perpendicular to the normal line of the semiconductor substrate 200.

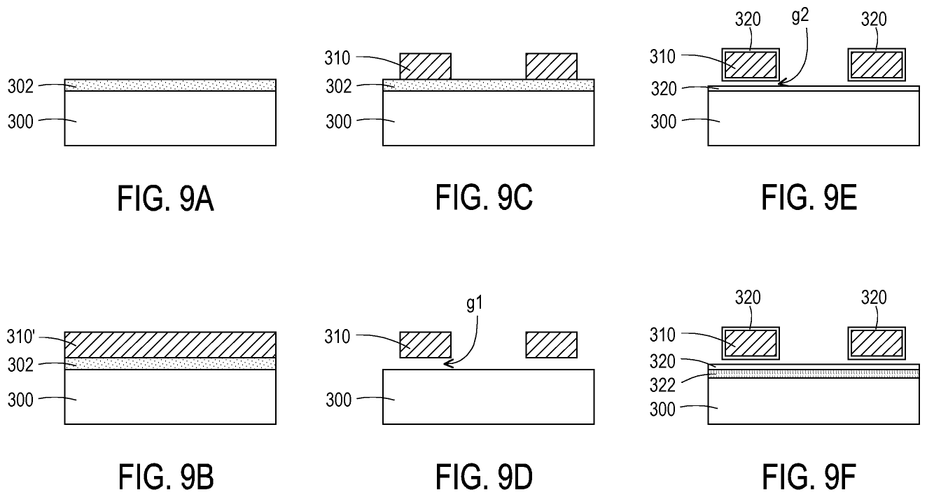

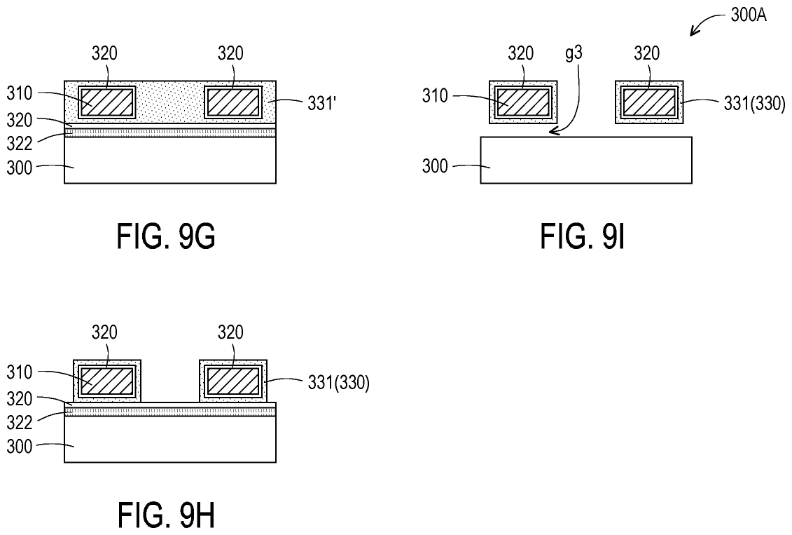

FIGS. 9A to 9G are schematic cross-sectional views illustrating structures formed at various stages of a method of forming an inductor 300A according to some embodiments of the present disclosure.

Referring to FIG. 9A, a semiconductor substrate 300 is provided and a sacrificial layer 302 is formed on the semiconductor substrate 300. The semiconductor substrate 300 may be similar to the semiconductor substrate 200 in FIG. 7A. The sacrificial layer 302 may be formed of silicon nitride, silicon oxide, silicon oxynitride, some other suitable dielectric(s), or any combination of the foregoing by any suitable method known in the art, such as chemical vapor deposition (CVD), plasma enhanced CVD (PECVD), a combination thereof, or the like.

Referring to FIGS. 9B and 9C, a conductive core 310 is formed on the sacrificial layer 302. The conductive core 310 may be formed by the following steps, which is not limited. For example, in FIG. 9B, a conductive material layer 310′ is formed on the sacrificial layer 302 first. The conductive material layer may be formed of the material similar as the material of the conductive core 110 described in FIG. 1 by any suitable method known in the art, such as CVD, physical vapor deposition (PVD), electro-chemical plating, a combination thereof, or the like. Then referring to FIG. 9C, the conductive material layer 310′ is patterned to form the conductive core 310. In detail, a patterned photoresist (not shown) may be formed on the conductive material layer 310′ and using the patterned photoresist as a mask, the conductive material layer 310′ is patterned through dry etching or other suitable methods to form the conductive core 310. FIG. 9C schematically shows two conductive cores 310, but it is not limited. The number of the conductive core and its pattern can be adjusted according to the actual requirement.

Referring to FIG. 9D, the sacrificial layer 302 is removed to form an air gap g1 between the conductive core 310 and the semiconductor substrate 300. The sacrificial layer 302 may be removed by wet etching and/or some other suitable type of etching. Although the conductive core 310 seems hanging in the air, the two ends of the conductive core 310 may connect to the semiconductor substrate 300 or the interconnect structure to form a bridge-like conductive core.

Referring to FIG. 9E, a dielectric film 320 is formed and surrounds the conductive core 310. The dielectric film 320 may be formed of the material similar as the material of the dielectric film 120 described in FIG. 1 by any suitable method known in the art, such as CVD, PECVD, a combination thereof, or the like. In some embodiments, the dielectric film 320 is further formed on the semiconductor substrate 300. The air gap g1 between the conductive core 310 and the semiconductor substrate may be reduced to an air gap g2 after forming the dielectric film 320. In some embodiments, there is no air gap between the conductive core 310 and the semiconductor substrate 300 after forming the dielectric film 320.

Referring to FIG. 9F, an anneal process is performed in oxygen environment to form an oxide layer 322 in the semiconductor substrate 300 closed to the dielectric film 320. In some embodiments, the dielectric film 320 formed on the semiconductor substrate 300 and the oxide layer 322 are regarded as sacrificial layers in the subsequent process. In some embodiments, the anneal process is optional. In other words, after forming the dielectric film 320, the anneal process may not be performed.

Referring to FIGS. 9G and 9H, a magnetic shell 330 is formed and surrounds the dielectric film 320. For example, the magnetic shell 330 includes a magnetic film 331. In FIG. 9G, a magnetic material layer 331′ is formed above the semiconductor substrate 300 and covers all around the conductive core 310 and the dielectric film 320. The magnetic material layer 331′ may be formed of the material similar as the material of the magnetic shell 130 described in FIG. 1 by any suitable method known in the art, such as PVD, CVD, a combination thereof or other suitable methods. Then, in FIG. 9H, the magnetic material layer 331′ is patterned to form a magnetic film 331. In detail, a patterned photoresist (not shown) may be formed on the magnetic material layer 331′ and using the patterned photoresist as a mask, the magnetic material layer 331′ is patterned through dry etching or other suitable methods to form the magnetic film 331 such that the dielectric film 320 covering on the conductive core 310 is surrounded by the magnetic film 331. In some embodiments, the magnetic material layer 331′ covering on the two opposite sides of the dielectric film 320 is removed to expose a portion of the side surfaces of the dielectric film 320 during the patterning process. In some embodiments, the dielectric film 320 formed on the semiconductor substrate 300 is partially exposed after forming the magnetic shell 330.

Referring to FIG. 9I, in some embodiments, the dielectric film 320 formed on the semiconductor substrate 300 and the oxide layer 322 is removed by wet etching and/or some other suitable type of etching to form an air gap g3 between the semiconductor substrate and the magnetic film 331. In other embodiments, the dielectric film 320 formed on the semiconductor substrate 300 and the oxide layer 322 may be remained, which is not limited.

Based on the above, the fabrication of the inductor 300A including the conductive core 310, the dielectric film 320 surrounding the conductive core and the magnetic shell 330 covering the dielectric film 320 is substantially completed. In some embodiments, the inductor 300A is formed during the back end of line (BEOL) process of the semiconductor die.

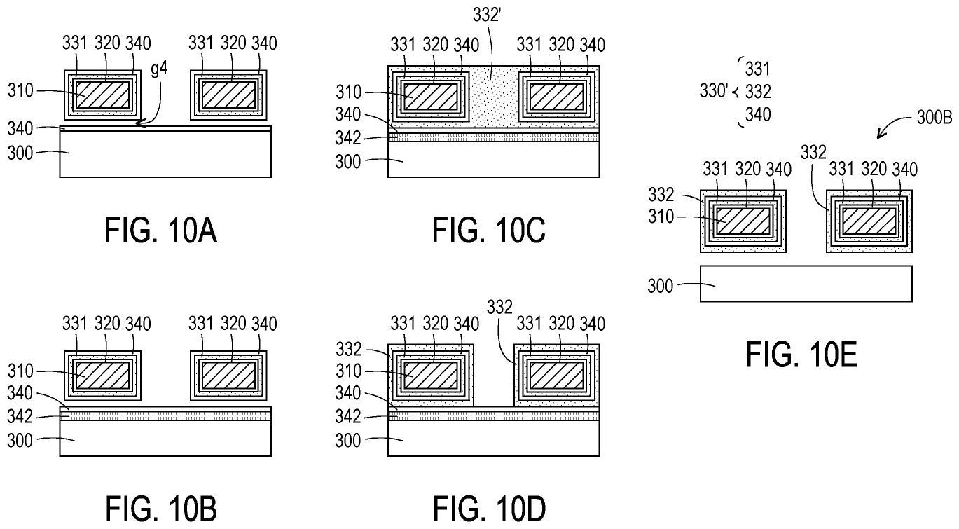

FIGS. 10A to 10E are schematic cross-sectional views illustrating structures formed at various stages of a method of forming an inductor 300B according to some embodiments of the present disclosure. It should be noted herein that, in embodiment provided in FIGS. 10A to 10E, element numerals and partial content of the embodiments provided in FIGS. 9A to 9I are followed, the same or similar reference numerals being used to represent the same or similar elements, and description of the same technical content being omitted. For a description of an omitted part, reference may be made to the foregoing embodiment, and the descriptions thereof are omitted herein. The process described in FIGS. 10A to 10E may be a continuation of the process described in FIGS. 9A to 9I.

Referring to FIG. 10A, an insulating film 340 is formed and surrounds the magnetic film 331. The insulating film 340 may be formed of the material similar as the material of the insulating film 141 described in FIG. 4 by any suitable method known in the art, such as CVD, PECVD, a combination thereof, or the like. In some embodiments, the insulating film 340 is further formed on the semiconductor substrate 300. The air gap g3 (shown in FIG. 9I) between the conductive core 310 and the semiconductor substrate 300 may be reduced to an air gap g4 after forming the insulating film 340. In some embodiments, there is no air gap between the conductive core 310 and the semiconductor substrate 300 after forming the insulating film 340.

Referring to FIG. 10B, an anneal process is performed in oxygen environment to form an oxide layer 342 in the semiconductor substrate 300 closed to the insulating film 340. In some embodiments, the insulating film 340 formed on the semiconductor substrate 300 and the oxide layer 322 is regarded as sacrificial layers in the subsequent process. In some embodiments, the anneal process is optional. In other words, after forming the insulating film 340, the anneal process may not be performed.

Referring to FIG. 10C, a magnetic material layer 332′ is formed above the semiconductor substrate 300 and covers all around the insulating film 340. The magnetic material layer 332′ may be formed of the material similar as the material of the magnetic shell 130 described in FIG. 1 by any suitable method known in the art, such as PVD, CVD, a combination thereof or other suitable methods.

Referring to FIG. 10D, the magnetic material layer 332′ is patterned to form a magnetic film 332. In detail, a patterned photoresist (not shown) may be formed on the magnetic material layer 332′ and using the patterned photoresist as a mask, the magnetic material layer 332′ is patterned through dry etching or other suitable methods to form the magnetic film 332 such that the insulating film 340 covering on the magnetic film 331 is surrounded by the magnetic film 332. This shows that the magnetic films 331 and 332 are separated by the insulating film 340. In some embodiments, the magnetic material layer 332′ covering on the two opposite sides of the insulating film 340 is removed to expose a portion of the side surfaces of the insulating film 340 during the patterning process. In some embodiments, the insulating film 340 formed on the semiconductor substrate 300 is partially exposed after forming the magnetic film 332.

Referring to FIG. 10E, in some embodiments, the insulating film 340 formed on the semiconductor substrate 300 and the oxide layer 342 is removed by wet etching and/or some other suitable type of etching to form an air gap between the semiconductor substrate 300 and the magnetic film 332. In other embodiments, the insulating film 340 formed on the semiconductor substrate 300 and the oxide layer 342 may be remained, which is not limited.

In the present embodiment, the magnetic shell 330′ is composed of the magnetic film 331, the insulating film 340 and the magnetic film 332. Based on the above, the fabrication of the inductor 300B including the conductive core 310, the dielectric film 320 surrounding the conductive core 310 and the magnetic shell 330′ covering the dielectric film 320 is substantially completed. It is appreciated that more magnetic films and insulating films may be formed as part of the magnetic shell 330′ by repeating the process similar as described in FIGS. 10A to 10E.

According to some embodiments of the present disclosure, an inductor is provided. The inductor includes a patterned wire structure. The patterned wire structure includes a conductive core, a dielectric film and a magnetic shell. The conductive core includes a pair of end surfaces and an outer surface between the pair of end surfaces. The dielectric film covers the outer surface. The magnetic shell covers the dielectric film. The dielectric film is between the conductive core and the magnetic shell.

According to some embodiments of the present disclosure, an inductor is provided. The inductor includes a patterned wire structure. The patterned wire structure includes a conductive core, a dielectric film and a magnetic shell. The conductive core includes a pair of end surfaces and an outer surface between the pair of end surfaces. The dielectric film covers the outer surface. The magnetic shell covers is disposed on at least two sides of the dielectric film.

According to some embodiments of the present disclosure, a method of forming an inductor is provided. The method includes the following steps. A sacrificial layer is formed on a semiconductor substrate. A conductive core is formed on the sacrificial layer. The sacrificial layer is removed to form an air gap between the conductive core and the semiconductor substrate. A dielectric film is formed and surrounds the conductive core. A magnetic shell is formed and surrounds the dielectric film.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An inductor, comprising:
a patterned wire structure, comprising:
a conductive core comprising a pair of end surfaces and an outer surface between the pair of end surfaces;
a dielectric film covering the outer surface; and
a magnetic shell covering the dielectric film, wherein the dielectric film is between the conductive core and the magnetic shell.

2. The inductor according to claim 1, wherein a shape of a cross-section of the conductive core comprises a circular shape, an oval shape or a polygonal shape, and a normal line of the cross-section parallels to an extending direction of the conductive core.

3. The inductor according to claim 1, wherein the patterned wire structure is embedded in a semiconductor die, and the semiconductor die comprising a semiconductor substrate and an interconnect structure on the semiconductor substrate.

4. The inductor according to claim 3, wherein an extending direction of a portion of the patterned wire structure is substantially parallel to a normal line of the semiconductor substrate.

5. The inductor according to claim 1, wherein an extending direction of a portion of the patterned wire structure is substantially perpendicular to a normal line of the semiconductor substrate.

6. The inductor according to claim 1, wherein the patterned wire structure extends along a line path, a spiral path or a serpentine path.

7. The inductor according to claim 1, wherein the magnetic shell comprises
a first magnetic film covering an outer surface of the dielectric film;
a second magnetic film; and
a first insulating film between the first magnetic film and the second magnetic film.

8. The inductor according to claim 1, wherein the magnetic shell comprises magnetic films covering the dielectric film, and the dielectric film covers the outer surface and the pair of end surfaces of the conductive core.

9. The inductor according to claim 1, wherein the magnetic shell comprises magnetic films and at least one insulating film, and the magnetic films are spaced apart from one other by the at least one insulating film.

10. The inductor according to claim 1, wherein the magnetic shell comprises a magnetic film having a thickness between about 0.06 μm and about 0.5 μm.

11. An inductor, comprising:
a patterned wire structure, comprising:
a conductive core comprising a pair of end surfaces and an outer surface between the pair of end surfaces;
a dielectric film covering the outer surface; and
a magnetic shell disposed on at least two sides of the dielectric film.

12. The wire structure according to claim 11, wherein the magnetic shell comprises a first portion and a second portion, and the first portion and the second portion are disposed on two opposite sides of the dielectric film respectively.

13. The wire structure according to claim 12, wherein the first portion and the second portion are disconnected.

14. The wire structure according to claim 11, wherein the dielectric film has four sides, and the magnetic shell is disposed on three of the four sides of the dielectric film.

15. The wire structure according to claim 11, wherein one side of the dielectric film is exposed.

16. The wire structure according to claim 11, wherein the dielectric film covers the outer surface and the pair of end surfaces of the conductive core and the magnetic shell surrounds the dielectric film.

17. A method of forming an inductor, comprising:
forming a sacrificial layer on a semiconductor substrate;
forming a conductive core on the sacrificial layer;
removing the sacrificial layer to form an air gap between the conductive core and the semiconductor substrate;
forming a dielectric film surrounding the conductive core;
forming a magnetic shell surrounding the dielectric film.

18. The manufacturing method according to claim 17, wherein the dielectric film is further formed on the semiconductor substrate.

19. The manufacturing method according to claim 18, further comprising:
removing the dielectric film formed on the semiconductor substrate.

20. The manufacturing method according to claim 19, wherein before removing the dielectric film formed on the semiconductor substrate, the dielectric film formed on the semiconductor substrate is partially exposed after forming the magnetic shell.
